(19) United States
(12) Patent Application Publication
(10) Pub. No.: US 2018/0025900 A1
(43) Pub. Date: Jan. 25, 2018

(54) ALKALI METAL AND ALKALI EARTH METAL REDUCTION

(71) Applicant: Applied Materials, Inc., Santa Clara, CA (US)

(72) Inventors: Soonam Park, Sunnyvale, CA (US); Mang-Mang Ling, San Jose, CA (US); Toan Q. Tran, San Jose, CA (US); Dmitry Lubomirsky, Cupertino, CA (US)

(73) Assignee: Applied Materials, Inc., Santa Clara, CA (US)

(21) Appl. No.: 15/217,651

(22) Filed: Jul. 22, 2016

(51) Int. Cl. H01L 21/02; H01L 21/3065

(52) U.S. Cl. CPC H01L 21/02057; H01L 21/3065; H01L 21/31116

(57) ABSTRACT

Methods of removing contamination from the surface of a substrate are described. The etch selectively removes alkali metals and alkali earth metals from substrates. The alkali metals may include sodium, lithium, rubidium or potassium and the alkali earth metals may include calcium. For example, the etch may remove contaminants by generating and then desorbing volatile chemical species from the substrate. A hydrogen-and-oxygen-containing precursor or combination of precursors is flowed into a remote plasma to form plasma effluents. The plasma effluents are then flowed into the substrate processing region to react with the substrate and remove an alkali metal and/or an alkali earth metal from the surface of the substrate. No local plasma excites the plasma effluents in embodiments.

### FIELD

The embodiments described herein relate to selectively removing material.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers or thinning lateral dimensions of features already present on the surface. Often it is desirable to have an etch process which etches one material faster than another helping e.g. a pattern transfer process proceed. Such an etch process is said to be selective of the first material. As a result of the diversity of materials, circuits and processes, etch processes have been developed that selectively remove one or more of a broad range of materials.

Dry etch processes are often desirable for selectively removing material from semiconductor substrates. The desirability stems from the ability to gently remove material from miniature structures with minimal physical disturbance. Dry etch processes also allow the etch rate to be abruptly stopped by removing the gas phase reagents. Dry-etch processes may involve the exposure of a substrate to plasma-excited species. Contaminants may be introduced to the substrate surface from chamber walls by plasma-excited species especially for local plasmas. Methods are needed to preferentially remove these redistributed contaminants from the surface of the substrate prior to further processing.

### SUMMARY

Methods of removing contamination from the surface of a substrate are described. The etch selectively removes alkali metals and alkali earth metals from substrates. The alkali metals may include sodium, lithium, rubidium or potassium and the alkali earth metals may include calcium. For example, the etch may remove contaminants by generating and then desorbing volatile chemical species from the substrate. A hydrogen-and-oxygen-containing precursor or combination of precursors is flowed into a remote plasma to form plasma effluents. The plasma effluents are then flowed into the substrate processing region to react with the substrate and remove an alkali metal and/or an alkali earth metal from the surface of the substrate. No local plasma excites the plasma effluents in embodiments.

Embodiments described herein include methods of cleaning a substrate. The methods include etching a substrate. Etching the substrate contaminates an exposed portion of the substrate with a first concentration of a contaminant selected from the group of elements consisting of sodium, potassium, lithium, rubidium and calcium. The first concentration is greater than 1×10¹¹/cm². The methods further include reducing the concentration of the contaminant to below a second concentration of 1×10¹⁰/cm² by exposing the substrate to plasma-excited species formed in a remote plasma from a hydrogen-and-oxygen-containing precursor. Etching the substrate and reducing the concentration of the contaminant may occur in separate substrate processing regions within separate substrate processing chambers. On the other hand, etching the substrate and reducing the concentration of the contaminants may occur in the same substrate processing region without transferring the substrate from one substrate processing chamber to another.

Embodiments described herein include methods of removing a contaminant from the surface of a substrate. The methods include placing the substrate into a substrate processing region of a substrate processing chamber. The substrate includes an exposed portion. The methods further include etching the substrate by flowing an etching precursor into the substrate processing region while forming a local plasma in the substrate processing region. Etching the substrate redistributes a contaminant from an interior surface of the substrate processing chamber onto the substrate raising a first concentration of the contaminant above 1×10¹¹/cm². The methods further include flowing a second precursor into a remote plasma region within the substrate processing chamber and fluidly coupled to the substrate processing region by a showerhead. The methods further include forming plasma effluents by forming a remote plasma in the remote plasma region. The methods further include flowing the plasma effluents through the showerhead into the substrate processing region. The methods further include removing a portion of the contaminant from the surface of the substrate. The methods further include reducing the contamination from the first concentration to below 1×10¹⁰/cm². The methods further include removing the substrate from the substrate processing region.

The contaminant may include one or more of sodium (Na), potassium (K), lithium (Li), rubidium (Rb) or calcium (Ca) according to embodiments. The exposed portion of the substrate may be silicon, silicon oxide or silicon nitride in embodiments. The exposed portion of the substrate may consist only of elements other than sodium (Na), potassium (K), lithium (Li), rubidium (Rb) and calcium (Ca) according to embodiments.

Embodiments described herein include methods of removing contaminants from a substrate. The methods include placing a substrate into a substrate processing region of a substrate processing chamber. The substrate has an exposed portion contaminated with a first contamination concentration greater than 1×10¹¹/cm² of at least one of an alkali metal or an alkali earth metal. The methods further include forming plasma effluents in a remote plasma region by flowing H or O into the remote plasma region while forming a remote plasma. The remote plasma region is fluidly coupled to the substrate processing region. The methods further include flowing the plasma effluents into the substrate processing region. The methods further include reducing the contamination concentration from the first contamination concentration to a second contamination concentration less than 1×10¹⁰/cm².

The remote plasma region may be fluidly coupled to the substrate processing region by a showerhead. Flowing H or O may include flowing a hydrogen-and-oxygen-containing precursor into the remote plasma region. Flowing H or O may include flowing a hydrogen-containing precursor and an oxygen-containing precursor into the remote plasma region. Flowing H or O comprises flowing H and O into the remote plasma region. Flowing H or O may include flowing one of H₂, H₂O, H₂O₂, NH₃, O₂, O₃, N₂O, NO₂, or NO into the remote plasma region. The substrate processing region may be plasma-free during the operation of flowing the plasma effluents into the substrate processing region. The alkali metal may include one of sodium (Na), lithium (Li), rubidium (Rb) or potassium (K). The alkali earth metal may include calcium (Ca).

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### DESCRIPTION OF THE DRAWINGS

A further understanding of the nature and advantages of the disclosed embodiments may be realized by reference to the remaining portions of the specification and the drawings.

FIG. 1 is a flow chart of a contaminant removal process according to embodiments.

FIG. 2 is a flow chart of a contaminant removal process according to embodiments.

FIG. 3A shows a schematic cross-sectional view of a substrate processing chamber according to embodiments.

FIG. 3B shows a schematic cross-sectional view of a portion of a substrate processing chamber according to embodiments.

FIG. 3C shows a bottom view of a showerhead according to embodiments.

FIG. 4 shows a top view of an exemplary substrate processing system according to embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Methods of removing contamination from the surface of a substrate are described. The etch selectively removes alkali metals and alkali earth metals from substrates. The alkali metals may include sodium, lithium, rubidium or potassium and the alkali earth metals may include calcium. For example, the etch may remove contaminants by generating and then desorbing volatile chemical species from the substrate. A hydrogen-and-oxygen-containing precursor or combination of precursors is flowed into a remote plasma to form plasma effluents. The plasma effluents are then flowed into the substrate processing region to react with the substrate and remove an alkali metal and/or an alkali earth metal from the surface of the substrate. No local plasma excites the plasma effluents in embodiments.

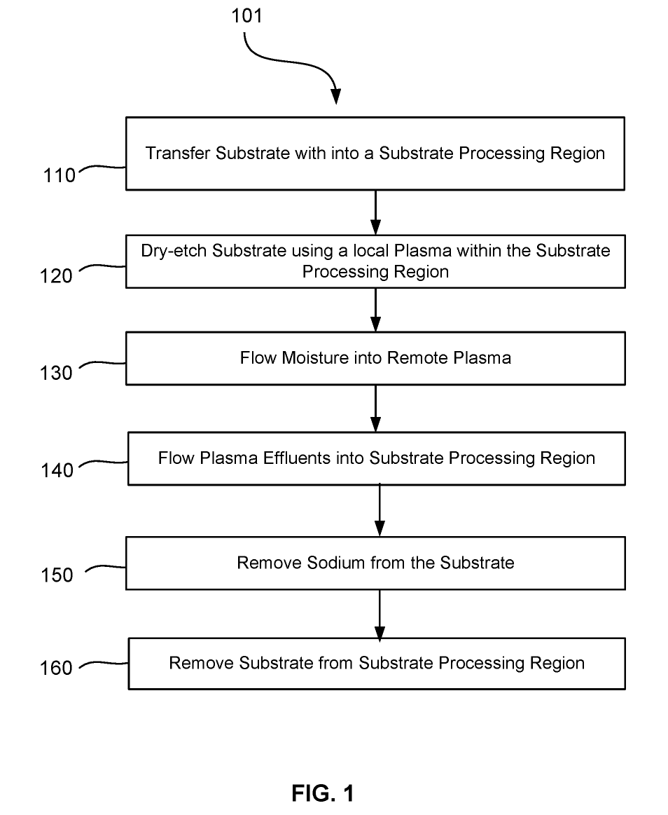

To better understand and appreciate the embodiments described herein, reference is now made to FIG. 1 which is a flow chart of a contaminant removal process 101 according to embodiments. The substrate is delivered into a substrate processing region (operation 110). Surfaces on the substrate are etched using wholly or partially local plasma to excite etchants to remove a portion of the substrate. The excited etchants also deleteriously redistribute a contaminant (e.g. sodium) from the interior walls of a substrate processing chamber containing the substrate processing region and redistribute the contaminant to the surface of the substrate (operation 120).

At this point the substrate may remain in the substrate processing region or may be moved to another substrate processing chamber and into another substrate processing region (within the second substrate processing chamber) to remove a portion of the contaminants as described. Moisture is flowed into a remote plasma region (operation 130) fluidly coupled to the substrate processing region, in embodiments, through a showerhead. Plasma effluents are formed in the remote plasma region and may be flowed through through-holes in the showerhead and into the substrate processing region (operation 140). Contaminants, e.g. sodium, is removed from the substrate by chemical action of the plasma effluents with the substrate in operation 150. The substrate may then be removed from the substrate processing region in operation 160.

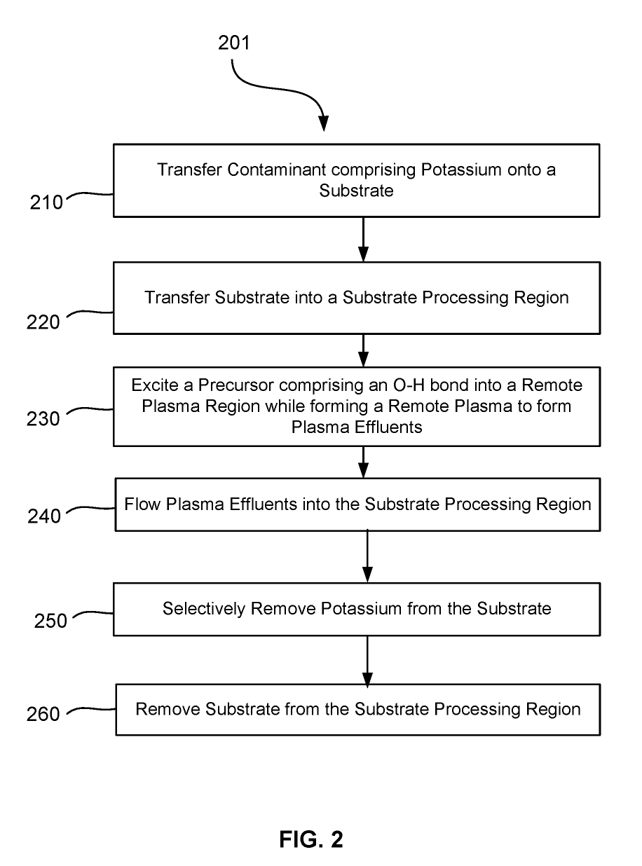

FIG. 2 is a flow chart of a contaminant removal process 201 according to embodiments. Surfaces on the substrate are contaminated, by any means, with a contaminant (e.g. potassium) in operation 210. The substrate is then transferred into the substrate processing region (operation 220) in preparation for removal of a portion of the contaminants as before. A precursor having an O—H bond is flowed into a remote plasma region fluidly coupled to the substrate processing region, in embodiments, through a showerhead. A remote plasma is formed in operation 230 to form plasma effluents. Plasma effluents are flowed through holes in the showerhead and into the substrate processing region (operation 240). Contaminants, e.g. the potassium, is removed from the substrate by the plasma effluents with the substrate in operation 250 and the substrate is removed from the substrate processing region in operation 260.

The process pressures and other aspects described for the remainder of the document apply to all embodiments herein. In all the embodiments described herein, generally speaking, a hydrogen and/or oxygen-containing precursors may be flowed into the remote plasma region to form the plasma effluents which remove the alkali metal or alkali earth metal contaminants. Flowing H or O into the remote plasma region may comprise flowing H and O into the remote plasma region and may comprise flowing a hydrogen-and-oxygen-containing precursor into the remote plasma region in embodiments. Flowing H or O may comprise flowing a hydrogen-containing precursor and an oxygen-containing precursor into the remote plasma region according to embodiments. Flowing H or O may comprise flowing H₂, H₂O, H₂O₂, O₂, O₃, N₂O, NO₂, or NO into the remote plasma region in embodiments. Combinations of these precursors may also be used.

The removal of the contaminants (operations 150 or 250) may involve reducing a concentration of the contaminants from a first concentration down to a second concentration. The first concentration may be greater than 1×10¹¹/cm² and the second contamination concentration may be less than 1×10¹⁰/cm² according to embodiments. The concentration may be measured with a surface sensitive measurement technique such as vapor phase decomposition (VPD) or inductively-coupled plasma mass spectrometry (ICP-MS). Other surface sensitive measurement techniques may be used which can distinguish among elements by a variety of means.

The contaminant may comprise or consist of an alkali metal from column 1a of the periodic table or may comprise or consist of an alkali earth metal from column 2a of the periodic table in embodiments. The contaminant may comprise or consist of sodium (Na), potassium (K) and/or calcium (Ca) according to embodiments. The remainder of the substrate or the exposed portion of the substrate, as described herein, may consist of elements other than sodium, potassium and calcium in embodiments. The remainder of the substrate or the exposed portion of the substrate may consist of elements other than alkali metals and/or alkali earth metals according to embodiments. The remainder of the substrate or the exposed portion of the substrate may comprise or consist of silicon, silicon oxide or silicon nitride in embodiments.

The methods described herein have been applied to substrates having contaminants including calcium, sodium, lithium, rubidium and potassium. The concentration of sodium was found to reduce by a factor of 100 and the concentration of potassium was found to reduce by a factor of 2 when hydrogen (H₂) was flowed into the remote plasma region to produce the plasma effluents. The concentration of sodium was found to reduce by a factor of 180 and the concentration of potassium was found to reduce by a factor of 40 when hydrogen (H₂O) was flowed into the remote plasma region to produce the plasma effluents.

The remote plasma power used to form the remote plasma, during all embodiments described herein, may be a radio-frequency (RF) power and may be between 10 watts and 10,000 watts, between 100 watts and 8,000 watts, between about 200 watts and about 7,500 watts, or between 3,000 watts and 6,000 watts in embodiments. The RF frequency applied to the remote plasma region may be low RF frequencies less than 200 kHz, high RF frequencies between 10 MHz and 15 MHz, or microwave frequencies greater than 1 GHz in embodiments. The plasma power may be capacitively-coupled (CCP) or inductively-coupled (ICP) into the remote plasma region.

Once the plasma effluents reach the substrate, the chemical reactions which remove contaminants may proceed thermally, excited only by the temperature of the substrate itself, according to embodiments. The substrate temperature may be between 40° C. and 500° C., between 50° C. and 400° C. or between 75° C. and 350° C. during operations 150 and/or 250, in embodiments, to assist in the desorption of chemical species formed on the surface of the substrate which contain alkali metals or alkali earth metals. The desorption reactions described herein have been found to proceed with a wide forgiving process window which aids manufacturability. In embodiments which rely on the temperature of the substrate to effect the etching reaction, the term “plasma-free” may be used herein to describe the substrate processing region during application using no or essentially no plasma power. Any plasma power in the substrate processing region may be referred to as a local plasma power or a “bias” plasma power. Any local plasma power may be kept below a small threshold amounts to enable the appropriate reactions to proceed. Any local plasma power applied to the substrate processing region may be less than 100 watts, less than 50 watts, less than 30 watts, less than 10 watts and may be 0 watts in embodiments.

The removal of alkali metals or alkali earth metals may proceed by the attachment of H and/or O to the alkali metal or alkali earth element to produce a volatile chemical species which desorbs from the substrate surface, in part, due to the elevated substrate temperature. O—H groups may accumulate (form a covalent bond) on the alkali metal or alkali earth element until volatility is achieved. For example, when trace elements of a contaminant such as sodium are present on the substrate at a first concentration greater than 1×10¹¹/cm², OH groups may bond to the contaminant to preferentially desorb the adsorbates thus formed at elevated substrate temperatures. The desorption may reduce the contaminant (e.g. sodium) concentration to below a second concentration of 1×10¹⁰/cm². The first concentration of a contaminant/trace element may be between 1×10¹¹/cm² and 1×10¹⁵/cm², between 1×10¹¹/cm² and 1×10¹⁴/cm² or between 1×10¹¹/cm² and 1×10¹³/cm² according to embodiments.

Absence (or reduction in magnitude) of any local plasma may be desirable to discourage contaminants from redepositing from the chamber walls onto the substrate. The term “plasma-free” will be used herein to describe the substrate processing region during application of no or essentially no plasma power to the substrate processing region. The plasma effluents described possess energetically favorable etch reaction pathways which enable the substrate processing region to be plasma-free during operations of removing contaminants. Stated another way, the electron temperature in the substrate processing region may be less than 0.5 eV, less than 0.45 eV, less than 0.4 eV, or less than 0.35 eV according to embodiments.

The pressure within the substrate processing region may be between 0.05 Torr and 20 Torr, between 0.1 Torr and 10 Torr, between 0.3 Torr and 2 Torr, between 0.5 Torr and 1.5 Torr in embodiments. The apertures (such as through-holes in the showerhead) may be large enough for the pressures in the remote plasma region and the substrate processing region to be roughly equal according to embodiments. Thus, the pressure within the substrate processing region may be between 0.05 Torr and 20 Torr, between 0.1 Torr and 10 Torr, between 0.3 Torr and 2 Torr, between 0.5 Torr and 1.5 Torr in embodiments. All pressures may apply to operations 130, 140, 150, 230, 240 and/or 250 according to embodiments.

Etching the substrate and reducing the concentration of the contaminant may occur in separate substrate processing regions within separate substrate processing chambers. On the other hand, etching the substrate and reducing the concentration of the contaminants may occur in the same substrate processing region without transferring the substrate from one substrate processing chamber to another.

A benefit of the contaminant removal processes described herein is the preferential removal of the alkali metal and alkali earth metal elements. In embodiments, only alkali metals and alkali earth metal elements are removed from the surface of the substrate. Removing the alkali metal and alkali earth metal elements may provide the benefit of improving the electrical performance of completed semiconductor devices. An additional benefit of the processes described herein may include performing the contaminant removal processes in the same substrate processing chamber used to perform the preceding operation which may reduce the necessary square footage required to house the equipment and reduce the cost-of-ownership (CoO). A further benefit of the contaminant removal processes described herein includes the lack of removal lack of removal or essential lack of removal of material other than alkali metals or alkali earth metals according to embodiments.

The hydrogen-containing precursor, the oxygen-containing precursor or hydrogen-and-oxygen-containing precursor may be supplied into the remote plasma region at a flow rate of between 5 sccm and 5,000 sccm, between 10 sccm and 3,000 sccm, between 25 sccm and 2,000 sccm, between 50 sccm and 1,500 sccm or between 75 sccm and 1,000 sccm in embodiments. A combination of an oxygen-containing precursor and a hydrogen-containing precursor may be supplied into the remote plasma region according to embodiments, in which case the combined flow rate may be within the aforementioned ranges. The flow rate of the plasma effluents may also lie within the aforementioned ranges in embodiments.

The flow of precursors into the remote plasma region and/or the substrate processing region may further include one or more relatively inert gases such as He, N₂, Ar. The inert gas may be included, for example, to improve process uniformity. Process uniformity is generally increased when helium is included. These additives are present in embodiments throughout this specification.

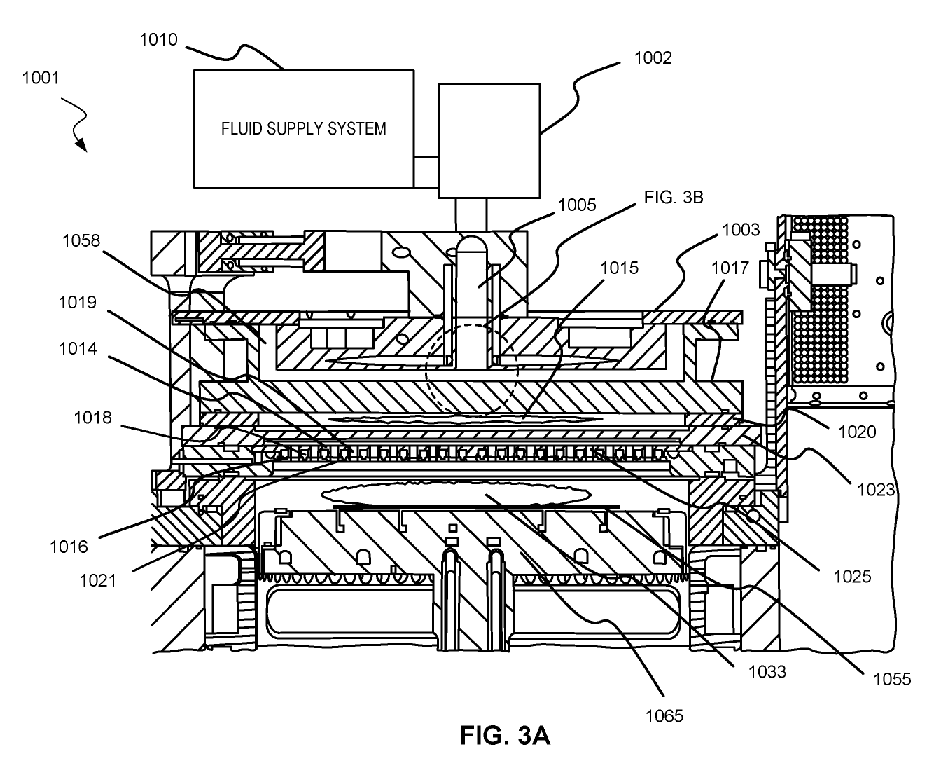

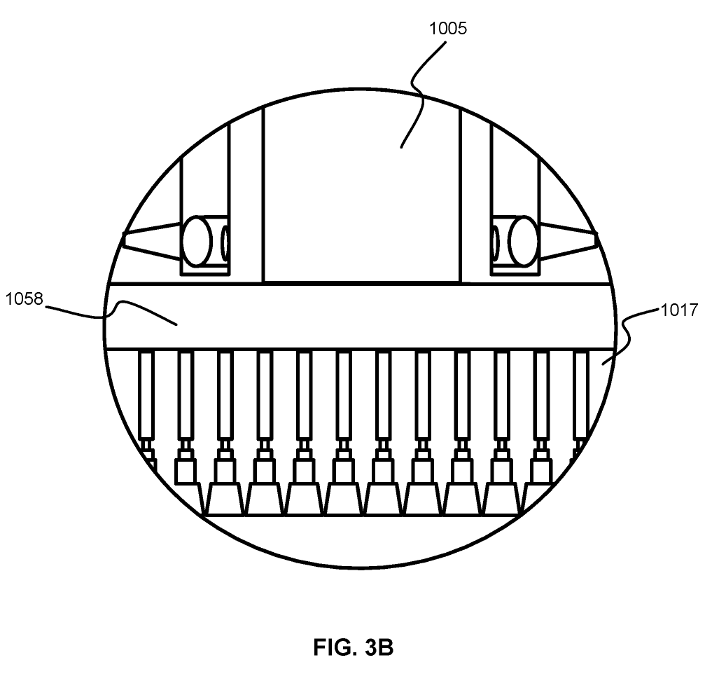

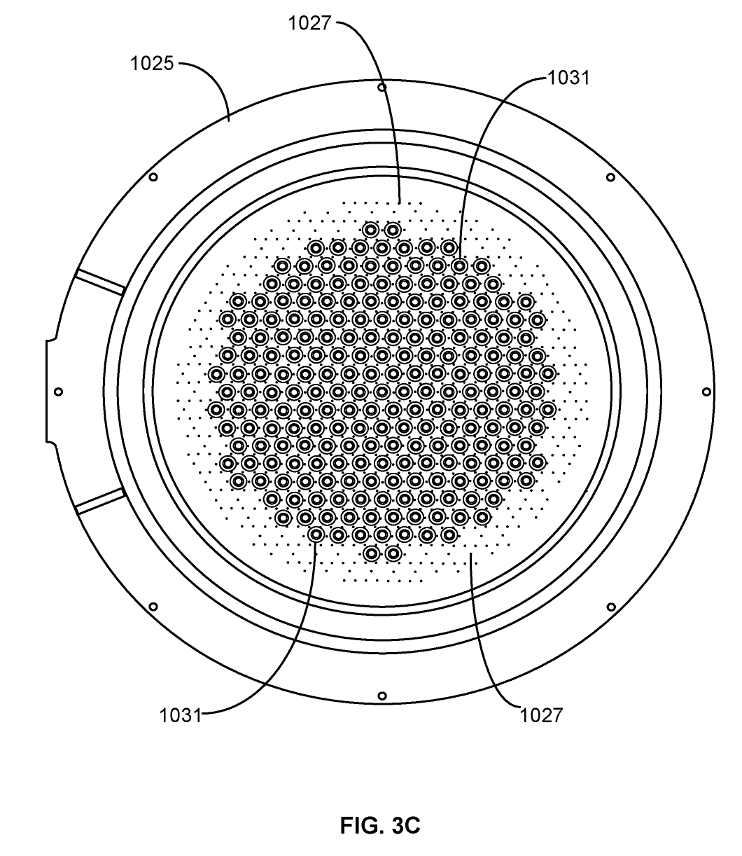

FIG. 3A shows a cross-sectional view of an exemplary substrate processing chamber 1001 with a partitioned plasma generation region within the processing chamber. During contaminant removal, a process gas may be flowed into chamber plasma region 1015 through a gas inlet assembly 1005. A remote plasma system (RPS) 1002 may optionally be included in the system, and may process a first gas which then travels through gas inlet assembly 1005. The process gas may be excited within RPS 1002 prior to entering chamber plasma region 1015. The hydrogen and/or oxygen-containing precursor may be excited in RPS 1002 and/or in the chamber plasma region 1015 but may be unexcited within the substrate processing region prior to reacting with substrate 1055.

A cooling plate 1003, faceplate 1017, ion suppressor 1023, showerhead 1025, and a substrate support 1065 (also known as a pedestal), having a substrate 1055 disposed thereon, are shown and may each be included according to embodiments. Pedestal 1065 may have a heat exchange channel through which a heat exchange fluid flows to control the temperature of the substrate. This configuration may allow the substrate 1055 temperature to be cooled or heated to maintain relatively low temperatures, such as between −20° C. to 200° C. Pedestal 1065 may also be resistively heated to relatively high temperatures, such as between 100° C. and 1100° C., using an embedded heater element.

Exemplary configurations may include having the gas inlet assembly 1005 open into a gas supply region 1058 partitioned from the chamber plasma region 1015 by faceplate 1017 so that the precursors flow through the holes in the faceplate 1017 into the chamber plasma region 1015. Structural and operational features may be selected to prevent significant backflow of plasma from the chamber plasma region 1015 back into the supply region 1058, gas inlet assembly 1005, and fluid supply system 1010. The structural features may include the selection of dimensions and cross-sectional geometries of the apertures in faceplate 1017 to deactivate back-streaming plasma. The operational features may include maintaining a pressure difference between the gas supply region 1058 and chamber plasma region 1015 that maintains a unidirectional flow of plasma through the showerhead 1025. The faceplate 1017, or a conductive top portion of the chamber, and showerhead 1025 are shown with an insulating ring 1020 located between the features, which allows an AC potential to be applied to the faceplate 1017 relative to showerhead 1025 and/or ion suppressor 1023. The insulating ring 1020 may be positioned between the faceplate 1017 and the showerhead 1025 and/or ion suppressor 1023 enabling a capacitively coupled plasma (CCP) to be formed in the first plasma region.

The plurality of holes in the ion suppressor 1023 may be configured to control the passage of the activated gas (including the ionic, radical, and/or neutral species) through the ion suppressor 1023. For example, the aspect ratio of the holes, or the hole diameter to length, and/or the geometry of the holes may be controlled so that the flow of ionically-charged species in the activated gas passing through the ion suppressor 1023 is reduced. The holes in the ion suppressor 1023 may include a tapered portion that faces chamber plasma region 1015, and a cylindrical portion that faces the showerhead 1025. The cylindrical portion may be shaped and dimensioned to control the flow of ionic species passing to the showerhead 1025. An adjustable electrical bias may also be applied to the ion suppressor 1023 as an additional means to control the flow of ionic species through the suppressor. The ion suppression element 1023 may function to reduce or eliminate the amount of ionically charged species traveling from the plasma generation region to the substrate. Uncharged neutral and radical species may still pass through the openings in the ion suppressor to react with the substrate.

Plasma power can be of a variety of frequencies or a combination of multiple frequencies. In the exemplary processing system the plasma may be provided by RF power delivered to faceplate 1017 relative to ion suppressor 1023 and/or showerhead 1025. The RF power may be between 10 watts and 10,000 watts, between 100 watts and 8,000 watts, between 200 watts and 7,500 watts, or between 3,000 watts and 6,000 watts in embodiments. The RF frequency applied in the exemplary processing system may be low RF frequencies less than 200 kHz, high RF frequencies between 10 MHz and 15 MHz, or microwave frequencies greater than 1 GHz in embodiments. The plasma power may be capacitively-coupled (CCP) or inductively-coupled (ICP) into the remote plasma region. A local plasma may be used in the substrate processing region to perform a preceding operation which undesirably introduces alkali metal or alkali earth metal contaminants onto the substrate prior to the contaminant removal methods described herein. The local plasma may have any or all of the remote plasma properties described herein (e.g. coupling, frequencies and powers).

A precursor, for example the hydrogen and/or oxygen-containing precursor, may be flowed into substrate processing region 1033 by embodiments of the showerhead described herein. Excited species derived from the process gas in chamber plasma region 1015 may travel through apertures in the ion suppressor 1023, and/or showerhead 1025 and react with an additional precursor flowing into substrate processing region 1033 from a separate portion of the showerhead. Alternatively, if all precursor species are being excited in chamber plasma region 1015, no additional precursors may be flowed through the separate portion of the showerhead. A local plasma may, alternatively or in combination, be present in substrate processing region 1033 during the selective etch process. While a plasma may be generated in substrate processing region 1033, a plasma may alternatively not be generated in substrate processing region 1033. Excited derivatives of the precursors (plasma effluents) may be created or enter the region above the substrate to remove species from the substrate.

FIG. 3B shows a detailed view of the features affecting the processing gas distribution through faceplate 1017. The gas distribution assemblies such as showerhead 1025 for use in the processing chamber section 1001 may be referred to as dual channel showerheads (DCSH) and are additionally detailed in the embodiments described in FIG. 3A as well as FIG. 3C herein. The dual channel showerhead may provide for etching processes that allow for separation of etchants outside of the processing region 1033 to provide limited interaction with chamber components and each other prior to being delivered into the processing region.

The showerhead 1025 may comprise an upper plate 1014 and a lower plate 1016. The plates may be coupled with one another to define a volume 1018 between the plates. The coupling of the plates may be so as to provide first fluid channels 1019 through the upper and lower plates, and second fluid channels 1021 through the lower plate 1016. The formed channels may be configured to provide fluid access from the volume 1018 through the lower plate 1016 via second fluid channels 1021 alone, and the first fluid channels 1019 may be fluidly isolated from the volume 1018 between the plates and the second fluid channels 1021. The volume 1018 may be fluidly accessible through a side of the gas distribution assembly 1025. Although the exemplary system of FIGS. 3A-3C includes a dual-channel showerhead, it is understood that alternative distribution assemblies may be utilized that maintain first and second precursors fluidly isolated prior to substrate processing region 1033. For example, a perforated plate and tubes underneath the plate may be utilized, although other configurations may operate with reduced efficiency or not provide as uniform processing as the dual-channel showerhead as described.

FIG. 3C is a bottom view of a showerhead 1025 for use with a processing chamber in embodiments. Showerhead 1025 corresponds with the showerhead shown in FIG. 3A. Through-holes 1031, which show a view of first fluid channels 1019, may have a plurality of shapes and configurations to control and affect the flow of precursors through the showerhead 1025. Small holes 1027, which show a view of second fluid channels 1021, may be distributed substantially evenly over the surface of the showerhead, even amongst the through-holes 1031, which may help to provide more even mixing of the precursors as they exit the showerhead than other configurations.

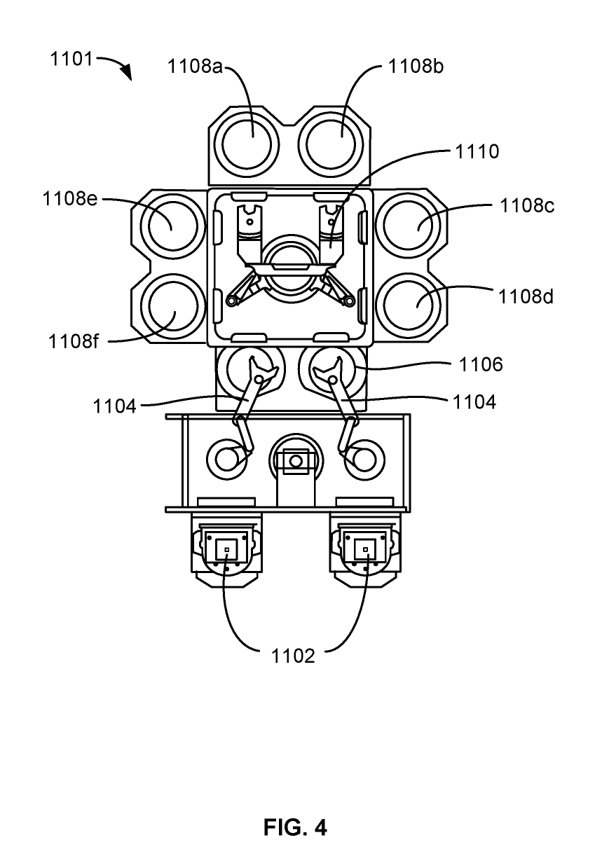

Embodiments of the substrate processing chambers may be incorporated into larger fabrication systems for producing integrated circuit chips. FIG. 4 shows one such processing system (mainframe) 1101 of deposition, etching, baking, and curing chambers in embodiments. In the figure, a pair of front opening unified pods (load lock chambers 1102) supply substrates of a variety of sizes that are received by robotic arms 1104 and placed into a low pressure holding area 1106 before being placed into one of the substrate processing chambers 1108a-f. A second robotic arm 1110 may be used to transport the substrate wafers from the holding area 1106 to the substrate processing chambers 1108a-f and back. Each substrate processing chamber 1108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

As used herein “substrate” may be a support substrate with or without layers formed thereon. The patterned substrate may be an insulator or a semiconductor of a variety of doping concentrations and profiles and may, for example, be a semiconductor substrate of the type used in the manufacture of integrated circuits. Exposed “metal” of the patterned substrate is predominantly a metal element but may include minority concentrations of other elemental constituents such as nitrogen, oxygen, hydrogen, silicon and carbon. Exposed “metal” may consist of or consist essentially of a metal element. Exposed “metal nitride” of the patterned substrate is predominantly nitrogen and a metal element but may include minority concentrations of other elemental constituents such as oxygen, hydrogen, silicon and carbon. Exposed “metal nitride” may consist of or consist essentially of nitrogen and a metal element. Exposed “silicon” or “polysilicon” of the patterned substrate is predominantly Si but may include minority concentrations of other elemental constituents such as nitrogen, oxygen, hydrogen and carbon. Exposed “silicon” or “polysilicon” may consist of or consist essentially of silicon. Exposed “silicon nitride” of the patterned substrate is predominantly silicon and nitrogen but may include minority concentrations of other elemental constituents such as oxygen, hydrogen and carbon. “Exposed silicon nitride” may consist essentially of or consist of silicon and nitrogen. Exposed “silicon oxide” of the patterned substrate is predominantly SiO₂ but may include minority concentrations of other elemental constituents (e.g. nitrogen, hydrogen, carbon). In some embodiments, silicon oxide regions etched using the methods disclosed herein consist essentially of silicon and oxygen.

The term “precursor” is used to refer to any process gas which takes part in a reaction to either remove material from or deposit material onto a surface. “Plasma effluents” describe gas exiting from the chamber plasma region and entering the substrate processing region. Plasma effluents are in an “excited state” wherein at least some of the gas molecules are in vibrationally-excited, dissociated and/or ionized states. A “radical precursor” is used to describe plasma effluents (a gas in an excited state which is exiting a plasma) which participate in a reaction to either remove material from or deposit material on a surface. “Radical-oxygen” are radical precursors which contain oxygen but may contain other elemental constituents. The phrase “inert gas” refers to any gas which does not form chemical bonds when etching or being incorporated into a layer. Exemplary inert gases include noble gases but may include other gases so long as no chemical bonds are formed when (typically) trace amounts are trapped in a layer.

A gap is an etched geometry having any horizontal aspect ratio. Viewed from above the surface, gaps may appear circular, oval, polygonal, rectangular, or a variety of other shapes. A “trench” is a long gap. A trench may be in the shape of a moat around an island of material whose aspect ratio is the length or circumference of the moat divided by the width of the moat. A “via” is a short gap with horizontal aspect ratio, as viewed from above, near unity. A via may appear circular, slightly oval, polygonal or slightly rectangular. A via may or may not be filled with metal to form a vertical electrical connection.

Having disclosed several embodiments, it will be recognized by those of skill in the art that various modifications, alternative constructions, and equivalents may be used without departing from the spirit of the disclosed embodiments. Additionally, a number of well known processes and elements have not been described to avoid unnecessarily obscuring the disclosed embodiments. Accordingly, the above description should not be taken as limiting the scope of the claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the disclosed embodiments, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or operations, but they do not preclude the presence or addition of one or more other features, integers, components, operations, acts, or groups.

1. A method of cleaning a substrate, the method comprising:
etching a substrate, wherein etching the substrate contaminates an exposed portion of the substrate with a first concentration of a contaminant selected from the group of elements consisting of sodium, potassium, lithium, rubidium and calcium, wherein the first concentration is greater than 1×10¹¹/cm²; and
reducing a concentration of the contaminant to below a second concentration of 1×10/cm² by exposing the substrate to plasma-excited species formed in a remote plasma from a hydrogen-and-oxygen-containing precursor.

2. The method of claim 1 wherein etching the substrate and reducing the concentration of the contaminant occur in the same substrate processing region without transferring the substrate from one substrate processing chamber to another.

3. A method of removing a contaminant from a surface of a substrate, the method comprising:
placing the substrate into a substrate processing region of a substrate processing chamber, wherein the substrate comprises an exposed portion;
etching the substrate by flowing an etching precursor into the substrate processing region while forming a local plasma in the substrate processing region, wherein etching the substrate redistributes a contaminant from an interior surface of the substrate processing chamber onto the substrate raising a first concentration of the contaminant above 1×10¹¹/cm²;
flowing a second precursor into a remote plasma region within the substrate processing chamber and fluidly coupled to the substrate processing region by a showerhead;
forming plasma effluents by forming a remote plasma in the remote plasma region;
flowing the plasma effluents through the showerhead into the substrate processing region;
removing a portion of the contaminant from the surface of the substrate;
reducing a contamination from the first concentration to below 1×10¹⁰/cm²; and
removing the substrate from the substrate processing region.

4. The method of claim 3 wherein the contaminant comprises sodium (Na), potassium (K), lithium (Li), rubidium (Rb) or calcium (Ca).

5. The method of claim 3 wherein the exposed portion of the substrate comprises silicon, silicon oxide or silicon nitride.

6. The method of claim 3 wherein the exposed portion of the substrate consists of elements other than sodium (Na), potassium (K), lithium (Li), rubidium (Rb) and calcium (Ca).

7. A method of removing contaminants from a substrate, the method comprising:
placing a substrate into a substrate processing region of a substrate processing chamber, wherein the substrate comprises an exposed portion contaminated with a first contamination concentration greater than 1×10¹¹/cm² of at least one of an alkali metal or an alkali earth metal;
forming plasma effluents in a remote plasma region by flowing H or O into the remote plasma region while forming a remote plasma, wherein the remote plasma region is fluidly coupled to the substrate processing region;
flowing the plasma effluents into the substrate processing region; and
reducing a contamination concentration from the first contamination concentration to a second contamination concentration less than 1×10¹⁰/cm².

8. The method of claim 7 wherein the remote plasma region is fluidly coupled to the substrate processing region by a showerhead.

9. The method of claim 7 wherein flowing H or O comprises flowing a hydrogen-and-oxygen-containing precursor into the remote plasma region.

10. The method of claim 7 wherein flowing H or O comprises flowing a hydrogen-containing precursor and an oxygen-containing precursor into the remote plasma region.

11. The method of claim 7 wherein flowing H or O comprises flowing H and O into the remote plasma region.

12. The method of claim 7 wherein flowing H or O comprises flowing one of H₂, H₂O, H₂O₂, NH₃, O₂, O₃, N₂O, NO₂, or NO into the remote plasma region.

13. The method of claim 7 wherein the substrate processing region is plasma-free during the flowing the plasma effluents into the substrate processing region.

14. The method of claim 7 wherein the alkali metal comprises one of sodium (Na), lithium (Li), rubidium (Rb) or potassium (K).

15. The method of claim 7 wherein the alkali earth metal comprises calcium (Ca).
